(19) United States
(12) Patent Application Publication
(10) Pub. No.: US 2007/0148979 A1
(43) Pub. Date: Jun. 28, 2007

(54) Method for fabricating semiconductor device having top round recess pattern

(75) Inventors: Hae-Jung Lee, Ichon-shi (KR); Yong-Tae Cho, Ichon-shi (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: HYNIX SEMICONDUCTOR INC.

(21) Appl. No.: 11/413,162

(22) Filed: Apr. 28, 2006

(30) Foreign Application Priority Data
Dec. 28, 2005 (KR) 2005-0132497

(51) Int. Cl. C23F 1/00; H01L 21/461; B44C 1/22; H01L 21/302

(52) U.S. Cl. 438/700; 216/41; 438/706

(57) ABSTRACT

A method for forming a semiconductor device having a recess pattern with a rounded top corner is provided. The method includes forming an etch mask pattern including a patterned sacrificial layer and a patterned hard mask layer over a substrate; etching predetermined portions of exposed sidewalls of the patterned sacrificial layer to form an undercut; etching the substrate to a predetermined depth using the etch mask pattern as an etch mask to form a recess having top corners; and performing an isotropic etching process to round the top corners of the recess beneath the undercut.

### RELATED APPLICATION

The present application is based upon and claims the benefit of priority from Korean patent application No. KR 2005-0132497, filed in the Korean Patent Office on Dec. 28, 2005, the entire contents of which are incorporated herein by reference.

### TECHNICAL FIELD

The present invention relates to a method for fabricating a semiconductor device; and more particularly, to a method for fabricating a semiconductor device having a recess pattern with a rounded top corner.

### DESCRIPTION OF RELATED ARTS

As for a conventional method for forming a planar gate interconnection line, in which a gate is formed over a flat active region, as a semiconductor device has been highly integrated, a gate channel length has been gradually decreased, and an implantation doping concentration has been increased. Accordingly, due to an increased electric field, a junction leakage has been generated and thus, it becomes difficult to secure a refresh property of the device.

To improve the above mentioned limitations, a recess gate process which forms a gate after etching a substrate defined as an active region into a recess pattern is implemented as a method for forming the gate interconnection line. If the aforementioned recess gate process is used, it is possible to increase a channel length and decrease an implantation doping concentration, thereby improving a refresh property of the device.

FIGS. 1A to 1F are diagrams for describing a typical method for forming a recess gate. Particularly, FIGS. 1A to 1D illustrate substrate structures cut in a direction vertical to the recess gate. FIGS. 1E and 1F illustrate substrate structures cut in the same direction as the recess gate.

As shown in FIG. 1A, a plurality of device isolation layer 12 are formed in a substrate 11. An oxide layer 13 and a patterned hard mask polysilicon layer 14 are formed over the substrate 11. In more detail of the formation of the patterned hard mask polysilicon layers 14, although not illustrated, a photoresist mask layer is patterned over certain portions of the hard mask polysilicon layer to expose a region where a recess is to be formed. The hard mask polysilicon layer is then etched using patterned photoresist mask layer (not shown) as an etch mask. Afterwards, the patterned photoresist mask layer is removed.

As shown in FIG. 1B, the oxide layer 13 is etched using the patterned hard mask polysilicon layer 14 as an etch barrier. Herein, the patterned oxide layer is denoted with a reference numeral 13A. At this time, the substrate 11, which is not a target for etch, may be etched. Reference numeral 11A denotes a patterned substrate 11.

As shown in FIG. 1C, a plurality of recesses 15 are formed by etching the patterned substrate 11A in which the recesses are to be formed. Herein, a further patterned substrate is denoted with a reference numeral 11B. At this time, as illustrated in FIG. 1E, a horn ‘X’ may be formed over a bottom portion of the further patterned substrate 11B (i.e., the recessed active region).

Referring to FIG. 1D, an isotropic etching process is performed to remove the horn. FIG. 1F shows that the horn ‘X’ is removed by this isotropic etching process. However, another horn ‘Y’ may be generated over a top portion of the individual recess 15.

According to the conventional method, the isotropic etching process is performed to remove the horn that may be generated over the bottom portion of the oxide layer and the top portion of the recessed substrate region. However, the isotropic etching process may etch undesired portion of the substrate, and as a result, a final inspection critical dimension (FICD) may be increased. The horn may also be reacted as a new stress point.

### SUMMARY

The present invention provides a method for fabricating a semiconductor device to make a top portion of a recess rounded.

Consistent with the present invention, there is provided a method for forming a semiconductor device. The method includes forming an etch mask pattern including a patterned sacrificial layer and a patterned hard mask layer over a substrate; etching predetermined portions of exposed sidewalls of the patterned sacrificial layer to form an undercut; etching the substrate to a predetermined depth using the etch mask pattern as an etch mask to form a recess having top corners; and performing an isotropic etching process to round the top corners of the recess beneath the undercut.

Additional features and advantages of the invention will be set forth in part in the description which follows, and in part will be apparent from that description, or may be learned by practice of the invention. The features and advantages of the invention will be realized and attained by means of the elements and combinations particularly pointed out in the appended claims.

It is to be understood that both the foregoing general description and the following detailed description are exemplary and explanatory and are intended to provide further explanation of the invention as claimed.

### BRIEF DESCRIPTION OF THE DRAWINGS

The above and other features of the present invention will become better understood with respect to the following description of the preferred embodiments given in conjunction with the accompanying drawings, in which:

FIGS. 1A to 1F are diagrams for describing a typical method for fabricating a semiconductor device; and

FIGS. 2A to 2H are diagrams for describing a method for fabricating a semiconductor device consistent with embodiments of the present invention.

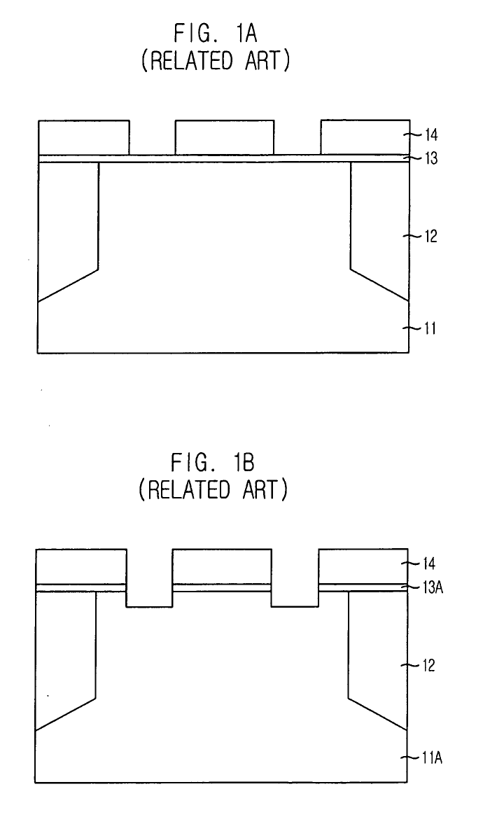

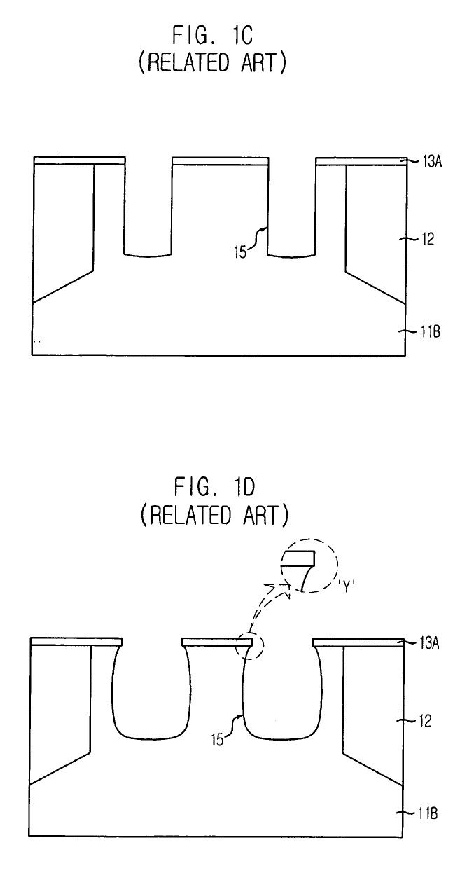

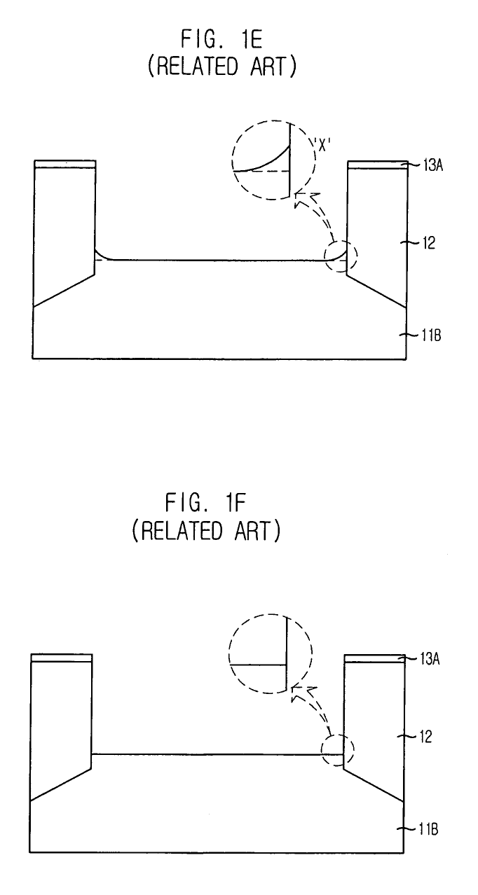

### DETAILED DESCRIPTION

Hereinafter, detailed descriptions of embodiments of the present invention will be provided with reference to the accompanying drawings.

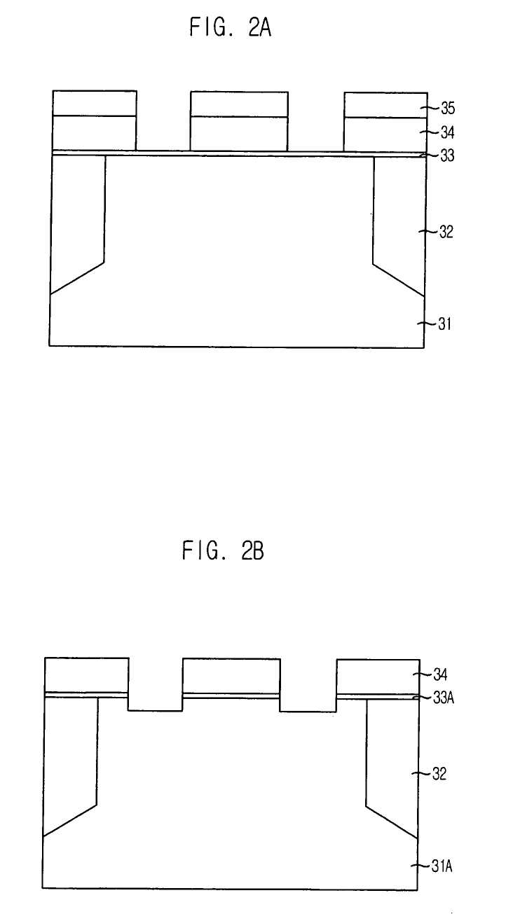

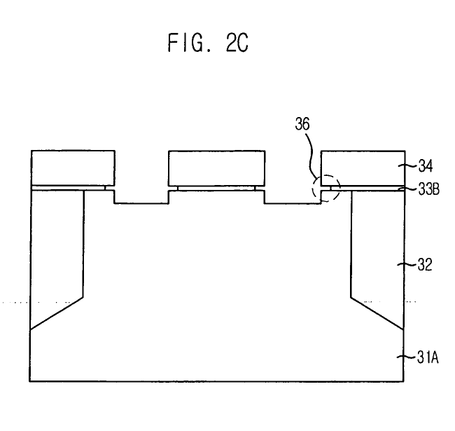

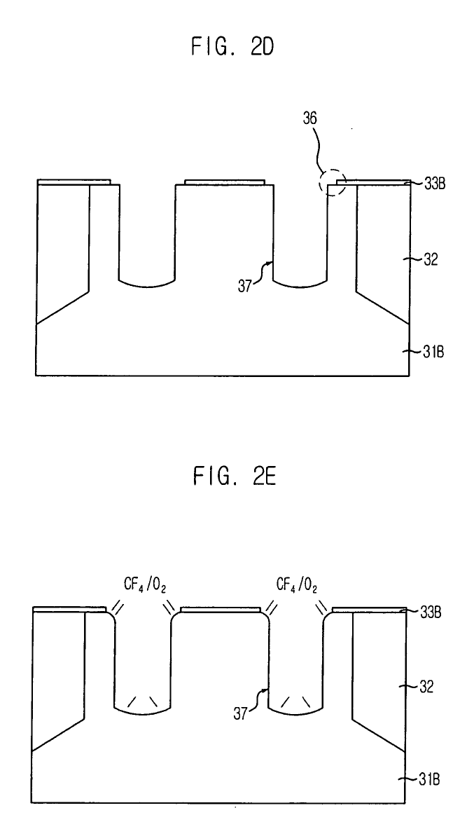

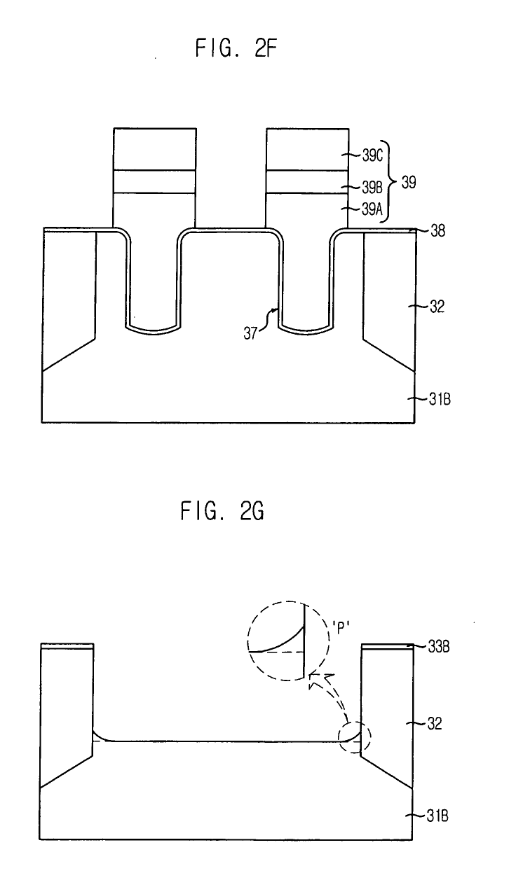

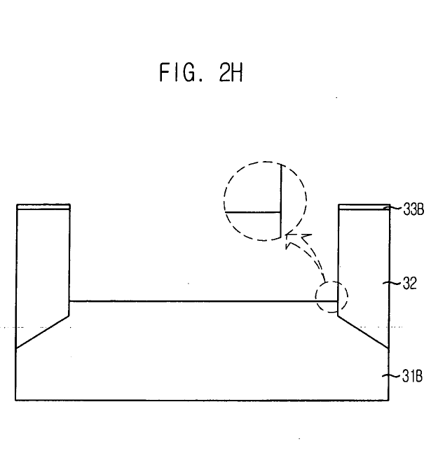

FIGS. 2A to 2H are diagrams for describing a method for fabricating a semiconductor device consistent with embodiments of the present invention. Particularly, FIGS. 2A to 2F illustrate substrate structures cut in a direction vertical to a recess gate. FIGS. 2G and 2H illustrate substrate structures cut in the same direction as a recess gate.

As shown in FIG. 2A, a plurality of device isolation layers 32 are formed in a substrate 31 through a shallow trench isolation (STI) process. Herein, the device isolation layers 32 define an active region, and each of the device isolation layers 32 is formed in a thickness of approximately 3,000 Å.

To form the device isolation layers 32, predetermined portions of the substrate 31 are etched, thereby forming a plurality of trenches. An insulation layer is filled into the trenches, and a chemical mechanical polishing (CMP) process is performed thereon.

Next, an etch mask pattern including a patterned anti-reflective coating layer 35 and a patterned hard mask layer 34 is formed. First, a sacrificial layer 33 is formed over the substrate 31 including the device isolation layers 32. At this time, the sacrificial layer 33 can be a pad oxide layer used during the process of forming the device isolation layers 32.

Over the sacrificial layer 33, the patterned hard mask layer 34 and the patterned anti-reflective coating layer 35 are formed. Although not shown, the process of forming the patterned hard mask layer 34 and the patterned anti-reflective coating layer 35 will be explained hereinafter. Particularly, a hard mask layer and an anti-reflective coating layer are sequentially formed over the sacrificial layer 33. Herein, the hard mask layer is formed of amorphous carbon. Since the amorphous carbon has a high etch selectivity with respect to silicon, it is possible to deposit the hard mask layer formed with the amorphous carbon more thinly than a hard mask layer formed with polysilicon. Also, the anti-reflective layer comprises silicon oxynitride (SiON). Then, a photoresist pattern is formed over the anti-reflective coating layer. To form the photoresist pattern, a photoresist layer is formed over the anti-reflective coating layer and then, patterned through a photo-exposure process and a developing process. Next, the anti-reflective coating layer and the hard mask layer are selectively subjected to a dry etching process by using the photoresist pattern as an etch mask. The hard mask layer may be etched with a plasma including hydrogen bromide (HBr), which provides a high selectivity in etching the hard mask layer with respect to the sacrificial layer. The photoresist pattern is removed when the etching process of the anti-reflective layer and the hard mask layer is finished.

As shown in FIG. 2B, the sacrificial layer 33 is selectively dry etched using the patterned anti-reflective coating layer 35 and the patterned hard mask layer 34 as an etch mask. The dry etching process is performed by using a plasma including a fluorocarbon based etch gas such as tetrafluoromethane (CF₄) gas. The dry etching process may be carried out in-situ, i.e., at the same chamber where the etching process of the hard mask layer is carried out, ex-situ, i.e., at a chamber different from where the hard mask layer is etched. During the dry etching process, the substrate 31, which is not a target for etching, is also etched. Herein, a patterned substrate is denoted with a reference numeral 31A.

When the sacrificial layer 33 is etched, the pattered anti-reflective coating layers 35 are etched away. Herein, a reference numeral 33A denotes a first patterned sacrificial layer. As a result, another etch mask pattern including the first patterned sacrificial layer 33A and the patterned hard mask layer 34 is formed.

Referring to FIG. 2C, predetermined portions of exposed sidewalls of the patterned sacrificial layer 33A are wet etched, thereby forming an undercut 36. The wet etching process uses one of diluted buffered oxide etchant (BOE) and a diluted solution of hydrogen fluoride (HF). A reference numeral 33B denotes a second patterned sacrificial layer with the undercuts 36.

As show in FIG. 2D, the patterned substrate 31A is selectively etched using the patterned hard mask layer 34 as an etch mask, thereby forming a plurality of recesses 37. Herein, a further patterned substrate is denoted with a reference numeral 31B. The recesses 37 are formed through a dry etching process. The dry etching process is carried out at a high density plasma apparatus (e.g., an inductively coupled plasma reactor) using a plasma obtained by mixing chlorine (Cl₂) gas, hydrogen bromide (HBr) gas and oxygen (O₂) gas.

At this time, when the recesses 37 are formed, the patterned hard mask layer 34 formed with the amorphous carbon are not removed because the patterned hard mask layer 34 has a high etch selectivity to silicon.

Thus, a process removing the patterned hard mask layer 34 needs to be performed separately. The patterned hard mask layer 34 can be removed using an oxygen plasma.

Meanwhile, as illustrated in FIG. 2G, a horn ‘P’ is formed over a bottom portion of the further patterned substrate 31B (i.e., the recessed active region) contacting the device isolation layers 32.

Referring to FIG. 2E, the recesses 37 beneath the undercuts 36 are subjected to an isotropic etching process, thereby making top corners of the recesses 37 rounded.

Herein, the isotropic etching process may be a dry etching process. The isotropic etching process may be carried out in an ICP reactor using a plasma obtained by mixing fluorine based gas and oxygen gas. At this time, the fluorine based gas includes CF₄ gas. Also, a bias power is not applied to the isotropic etching process, but a source power is supplied to the isotropic etching process.

As illustrated in FIG. 2H, the horn ‘P’ formed over the bottom portion of the recessed active region is simultaneously removed during the isotropic etching process.

Accordingly, the top corners of the recesses 37 become rounded, and the horn ‘P’ is removed. The removal of the horn ‘P’ indicates that a stress point of leakage current is removed and then, a refresh characteristic can be improved.

Referring to FIG. 2F, the second patterned sacrificial layer 33B is removed by performing a cleaning process. The cleaning process uses a solution of HF or BOE.

Next, a gate oxide layer 38 is formed over the entire surface of the further patterned substrate 31B including the recesses 37.

Then, a plurality of gate patterns 39 are formed over the gate oxide layer 38. A portion of the individual gate pattern 39 is buried into the individual recess 37 and the other portion of the individual gate pattern 39 projects above the further patterned substrate 31B. Each of the gate patterns 39 is formed by stacking a metal interconnection layer 39A, a gate electrode 39B and a gate hard mask 39C.

Consistent with the present invention, an undercut is formed in a sacrificial layer. Then, an isotropic etching process is performed, thereby simultaneously rounding a top corner of a recess and removing a horn formed over a bottom portion of a recess of an active region.

Consistent with the present invention, a stress point of a leakage current is removed, thereby improving reliability of a gate oxide layer, the scale of integration of a device, and yields of products.

While the present invention has been described with respect to certain preferred embodiments, it will be apparent to those skilled in the art that various changes and modifications may be made without departing from the spirit and scope of the invention as defined in the following claims.

What is claimed is:

1. A method for forming a semiconductor device comprising:
forming an etch mask pattern including a patterned sacrificial layer and a patterned hard mask layer over a substrate;
etching predetermined portions of exposed sidewalls of the patterned sacrificial layer to form an undercut;
etching the substrate to a predetermined depth using the etch mask pattern as an etch mask to form a recess having top corners; and
performing an isotropic etching process to round the top corners of the recess beneath the undercut.

2. The method of claim 1, wherein the hard mask layer includes amorphous carbon.

3. The method of claim 1, wherein the isotropic etching process is performed using a plasma obtained by mixing fluorine based gas and oxygen (O₂) gas.

4. The method of claim 3, wherein the fluorine based gas includes tetrafluoromethane (CF₄) gas.

5. The method of claim 4, wherein the isotropic etching process is performed using a source power without a bias power.

6. The method of claim 1, wherein the undercut is formed through a wet etching process.

7. The method of claim 6, wherein the wet etching process uses one of a diluted solution of hydrogen fluoride (HF) and diluted buffered oxide etchant (BOE).

8. The method of claim 1, wherein the forming of the etch mask pattern includes:
forming a sacrificial layer, a hard mask layer, and an anti-reflective coating layer over the substrate;
forming a photoresist pattern over the anti-reflective coating layer;
etching the anti-reflective coating layer and the hard mask layer using the patterned photoresist pattern as an etch barrier; and
etching the sacrificial layer using the patterned anti-reflective coating layer and the patterned hard mask.

9. The method of claim 8, wherein the etching of the hard mask layer is performed using a plasma including hydrogen bromide (HBr) to have a high etch selectivity to the sacrificial layer.

10. The method of claim 8, wherein the etching of the sacrificial layer is performed using a plasma including fluorocarbon based etch gas.

11. The method of claim 10, wherein the fluorocarbon based etch gas includes CF₄ gas.

12. The method of claim 10, wherein the etching of the sacrificial layer is performed in-situ at the same chamber where the hard mask layer is etched.

13. The method of claim 10, wherein the etching of the sacrificial layer is performed ex-situ at a chamber different from where the hard mask layer is etched.

14. The method of claim 1, wherein the forming of the recess is performed in a high density plasma apparatus such as an inductively coupled plasma reactor using a plasma obtained by mixing chlorine (Cl₂) gas, hydrogen bromide (HBr) gas and oxygen (O₂) gas.

15. The method of claim 8, wherein the hard mask layer includes amorphous carbon.
